(19) United States
(12) Patent Application Publication
(10) Pub. No.: US 2014/0298741 A1
(43) Pub. Date: Oct. 9, 2014

(54) INTEGRATED CABINET AND BUILDING STRUCTURE

(71) Applicant: Cannon Technologies Limited, New Milton (GB)

(72) Inventor: Edward A. Reddicliffe, New Milton (GB)

(21) Appl. No.: 14/246,989

(22) Filed: Apr. 7, 2014

(30) Foreign Application Priority Data
Apr. 4, 2013 (GB) 1306107.2

(51) Int. Cl. H05K 7/20; E04C 2/52; E04B 1/343; E04B 1/70; E04B 1/66

(52) U.S. Cl. CPC H05K 7/20745; E04B 1/7076; E04B 1/66; E04B 1/34384; E04C 2/523; F24F 2007/003
USPC 52/302.1; 52/745.06; 52/741.4

(57) ABSTRACT

A method of providing a removable building structure containing computing equipment. The method comprises providing an array of cabinets. The cabinets are formed from vertical support pillars wherein at least some of the vertical support pillars are hollow and have apertures formed along their length and arranged to enable air flow through the posts to control the temperature within the building. A roof is supported by using the array of cabinets as a modular constructional element of the building structure to provide support providing outer walls for the building. Computing equipment is placed in the cabinets.

This invention relates generally to an integrated cabinet and building structure. The structure according to the present invention can be used, for example, in prefabricated buildings provided for storing computing and related (IT) equipment.

Modern IT rooms used for accommodating of computing equipment usually follow a standard layout which comprises rows or bays of racks or cabinets separated by parallel aisles. An essential requirement for many IT rooms is to provide adequate ventilation to allow air to flow and cool the IT equipment.

Prefabricated buildings are currently provided for applications such as IT rooms. Such prefabricated buildings use various types of roof beam or trusses to span the width of the room. If the rooms are required to be very wide, then the cost per square meter of the building increases because, as the trusses grow longer to match the span, they also increase in size and cost at a substantial rate. Similarly, the support columns or structural walls of the building also increase in mass and cost.

It is common practice for such prefabricated buildings to be placed within the shell of existing permanent buildings. The increased length and thickness of such trusses and walls, however, can constrain the freedom to place the prefabricated buildings inside the permanent buildings, because such trusses and walls sometimes interfere with existing roof trusses in the umbrella building. Increasing weight can also overstress some types of ground or floors on which these prefabricated buildings are placed.

Furthermore, such heavy building elements often need to be handled with a heavy mechanical plant and cranes which can obstruct the access to the building site. Also, the rental cost of handling such mechanical plant is high and sophisticated logistics are required.

Accordingly, there is a need for a low cost, simplified structural design for prefabricated buildings which still has sufficient structural strength. Furthermore, there is a need for a design which achieves a functional structure with reduced components for varying floor areas. Finally, the design should comply with the air flow requirements of IT rooms.

According to the present invention there is provided a method of providing a removable building structure containing computing equipment, the method comprising the steps of: providing an array of cabinets, the cabinets being formed from vertical support pillars wherein at least some of the vertical support pillars are hollow and have apertures formed along their length and arranged to enable air flow through the posts to control the temperature within the building; providing a roof supported by using the array of cabinets as a modular constructional element of the building structure to provide support providing outer walls for the building; and placing the computing equipment in the cabinets.

With the present invention, given that the columns provide a dual purpose of supporting the building structure and providing ventilation for cooling of elements within the building, it is possible to provide a structure which is simple to construct and has an optimised footprint. The provision of such columns enables ventilation and support to the extent that a building of two storeys can be provided with racks or cabinets on both storeys without needing additional support structures that can reduce the capacity of the building and/or provide a hindrance to access to individual racks or cabinets.

The structure also ensures that many components of the building can be prefabricated for ease of installation, regardless of the location of the building. By providing such a structure it is also possible to ensure that the building meets all safety requirements and that it is strong enough for a local environment without the need for digging of foundations with only a simple flat rigid floor, such as one which may be provided by a layer of concrete, being provided.

An example of the present invention will now be described with reference to the accompanying drawings, in which:

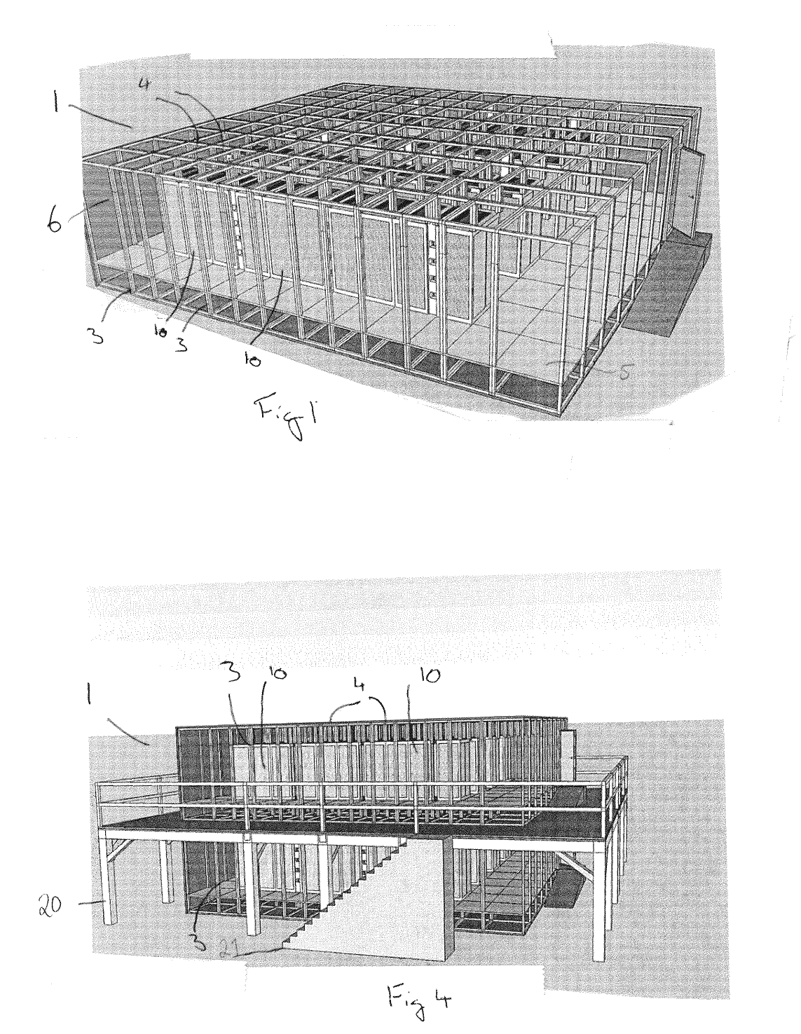

FIG. 1 is a side view of a partially constructed building according to the present invention;

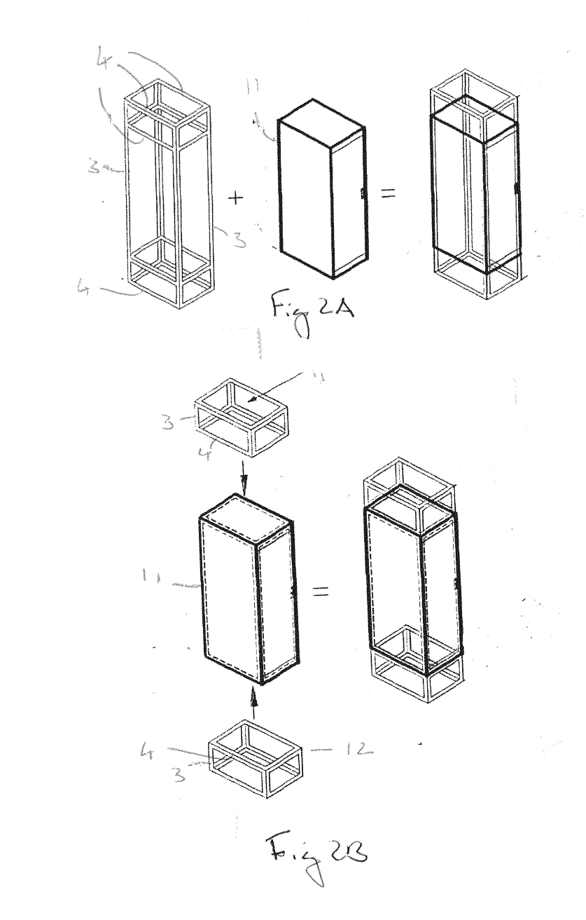

FIG. 2 shows two examples of integrated cabinet and structure components that can be employed with the present invention;

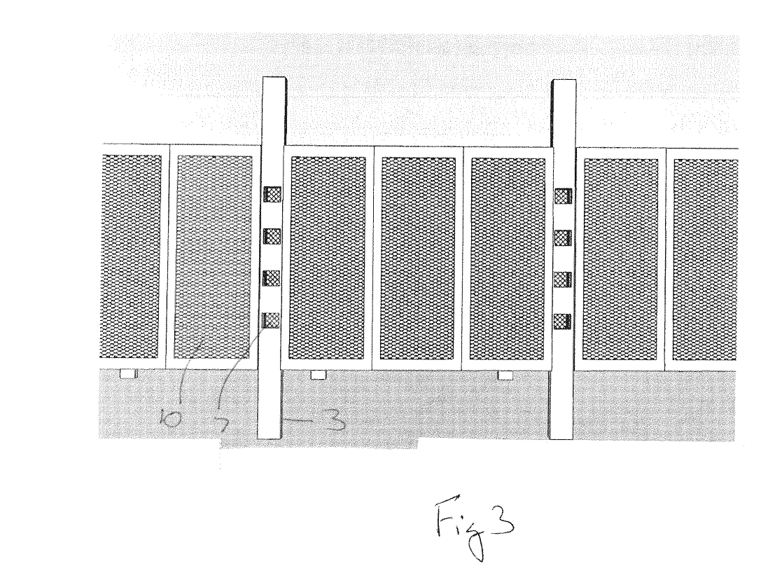

FIG. 3 is a side view of a partially constructed building according to the present invention highlighting columns used with the invention; and

FIG. 4 is a view of building according to the present invention with a single storey and with a second storey.

Referring to FIG. 1, a building structure 1 formed in accordance with the present invention is shown in partially constructed form. The building 1 is formed from a series of cabinet 10 and integrated structure components 3,4 each having support corner posts 3 that are positioned vertically and connected together by horizontal rails 4. Each integrated cabinet is of a standard size that enables the installation of IT equipment (not shown) within it either before or after the final building 1 has been constructed. Individual cabinets 10 are connected to adjacent cabinets in a series of rows with spacing between adjacent rows to enable access to both construction and support personnel. Additional support posts 3 and rails 4 can be provided around the periphery of the rows to provide access around the edge of the structure and provide support for external walls 6. The horizontal rails 4 are structured to enable support of a raised floor 5 which can then provide a recess under all the cabinets for access for cabling and to provide ventilation. When all the cabinets 2 are connected and the exterior wall 6 assembled the structure is strong and rigid enough to provide support for a roof or a floor of a subsequent storey for the building. The corner posts 3 and rails 4 are structured such that they do not provide an obstacle to the aisles between the rows of filled cabinets and the corner posts 3 and rails 4 can be mass produced and are of a type common to rack and building requirements. The positioning of the upper rails 4 can also be selected such that it is below the top position of the posts 3 to allow ventilation above the individual cabinets as well as access for cabling and other services.

FIGS. 2A and 2B show examples of cabinet and structure components that can be employed with the invention. In FIG. 2A the corner posts 3 are extended vertically upwards and/or downwards with respect to the top and base of cabinet frame 10. This generates additional space above and below the cabinet frame 10 to provide the recess as discussed above. The tops of the extended corner posts 3 of the resulting cabinet structure can conveniently support a roof or floor structure above them as shown in the other figures. This also enables the building roof or upper floor to be set at a height which is independent of cabinet height. As mentioned above, this additional generated space above or below the cabinet creates air-flow for cooling and/or for services such as pipe work, cabling and accessories. FIG. 2B shows an alternative configuration in which cabinet frames 10 have stacked sub-frames 11,12 to achieve a cabinet structure which is equivalent to the resulting structure shown in FIG. 2A. With this the vertical posts 3 can be divided into the desired height when stacked. The sub-sections can be assembled with the horizontal rails 4 to achieve complete sub-frames for ease of handling. By stacking these sub-frames on top of each other they desired total height for the room can be provided.

Such sub-frames can be located by pegs and bolted together and can have advantages over the examples shown in FIG. 2A in that they reduce the handling weight for individual components and the individual components are easy to accommodate before being assembled.

With either example the raised floor level that is provided can be formed from a series of tiles of standard sizes again for ease of construction. Whichever type of integrated cabinet and structural component is provided, be it that of FIG. 2A or FIG. 2B, such individual structures can be aligned with one another through a variety of connection systems, again such as a peg and bolt arrangement to provide a complete rigid structure with connected floor and roof supporting assemblies. Because of the rigidity of the overall structure, for most situations, it is not necessary for a deep foundation for the structure to be provided, rather all that is required is a simple slab floor without deep pilings.

FIG. 3 is a more detailed view from the side of a partially constructed building according to the present invention. Here a floor has been provided along with four rows of connected integrated cabinet structures, with certain upper parts of the integrated cabinet structures having been removed for ease of viewing. From this it can be seen that selected support posts 3, in this case one every three cabinets, are hollow structured to provide ventilation holes 7 whilst still providing support for the cabinets 10, floors and any roof or upper floor that is placed on it. The provision of ventilated support columns is particularly beneficial. Firstly they remove the need for additional ventilation components to be provided in addition to the integrated cabinet and support structure, reducing the number of components that are required. This reduces the overall weight and cost of the building and aids in the ability to provide, the need for additional structure components the ability to provide a second floor of cabinets. The ventilation holes also enable, if required, access to the interior of the individual posts to allow cabling to be passed through then also if necessary. This can avoid the need for trunking and routing components, again which increase building complexity, cost and whilst doing all of this they also ensure that adequate in ventilation can be provided throughout the building, and can be particularly directed to the relevant positions within the building to ensure adequate ventilation and therefore temperature control of the cabinets and their contents.

FIG. 4 shows a building 1 constructed in accordance with the present invention in which a second floor of cabinets is being provided with a structure similar to that shown in FIG. 1 for the first floor. Again, certain side exterior walls have been removed for ease of understanding. Here it can be seen that an external frame 20 can be provided around the exterior of the building to provide support for an access stair 21 as well as to ensure structural rigidity in areas where high winds or other environmental factors could induce high side forces on the building and structural integrity is required. Because of the strength of building 1 in view of the rigid structure formed by the connected cabinet units the building 1 is able to support a second floor of computing equipment whilst still retaining structural integrity, meaning that a lower footprint for the building, yet ease of construction is maintained. Furthermore, because of the ventilated support posts 3 it is possible to provide simple ventilation for either the lower floor and/or the upper floor without introducing additional components that would add weight to the structure as well as cost and increase construction complexity. The structure of the cabinets also ensures that installation of cabling for connection to the IT equipment, as well as support cabling for fire systems, etc. is achieved easily without the need for additional components on the exterior of the building and hence additional support structures.

1. A method of providing a removable building structure containing computing equipment, the method comprising the steps of:
providing an array of cabinets, the cabinets being formed from vertical support pillars wherein at least some of the vertical support pillars are hollow and have apertures formed along their length and arranged to enable air flow through the posts to control the temperature within the building;
providing a roof supported by using the array of cabinets as a modular constructional element of the building structure to provide support providing outer walls for the building; and
placing the computing equipment in the cabinets.

2. A method according to claim 1 wherein frames are provided in combination with at least some of the cabinets.

3. A method according to claim 1, wherein support members are provided between adjacent cabinets and/or frames.

4. A method according to claim 2, wherein horizontal members are provided between adjacent cabinets and/or frames at a position below their upper level in order to provide support for raised flooring.

5. A method according to claim 4, wherein the raised flooring is comprised of an array of tiles arranged between adjacent cabinets and/or frames.

6. A method according to claim 6, wherein at least one tile is a grill.

7. A method according to claim 1, wherein the roof is provided by forming a top panel on each cabinet, with sealing provided between adjacent panels to define a watertight roof

8. A method according to claim 1, wherein panels are attached to selected cabinets to define the outer walls and/or segregated compartments to improve thermal insulation values, fire resistance or acoustic attenuation.

9. A method according to claim 8, wherein at least one panel defining an outer wall has and internal skin provided with means for mounting equipment.

10. A method according to claim 1, wherein the roof has an internal skin provided with means for mounting equipment.

11. A method according to claim 1 further comprising the step of passing cabling through the apertures and the support posts for connection to the computing equipment in the cabinets.

12. A method according to claim 11 further comprising the step of forming a floor on to of a first array of cabinets, providing a second array of cabinets on top of that floor and wherein the roof is then supported by the second array of cabinets.

13. A building formed in accordance with the method of claim 1.

14. A method according to claim 2, wherein support members are provided between adjacent cabinets and/or frames.

15. A method according to claim 3, wherein horizontal members are provided between adjacent cabinets and/or frames at a position below their upper level in order to provide support for raised flooring.

16. A method according to claim 2, wherein the roof is provided by forming a top panel on each cabinet, with sealing provided between adjacent panels to define a watertight roof.

17. A method according to claim 3, wherein the roof is provided by forming a top panel on each cabinet, with sealing provided between adjacent panels to define a watertight roof.

18. A method according to claim 4, wherein the roof is provided by forming a top panel on each cabinet, with sealing provided between adjacent panels to define a watertight roof.

19. A method according to claim 5, wherein the roof is provided by forming a top panel on each cabinet, with sealing provided between adjacent panels to define a watertight roof.

20. A method according to claim 6, wherein the roof is provided by forming a top panel on each cabinet, with sealing provided between adjacent panels to define a watertight roof.
